(19) United States
(12) Patent Application Publication
(10) Pub. No.: US 2010/0164098 A1
(43) Pub. Date: Jul. 1, 2010

(54) SEMICONDUCTOR DEVICE INCLUDING A COST-EFFICIENT CHIP-PACKAGE CONNECTION BASED ON METAL PILLARS

(76) Inventors: Frank Kuechenmeister, Dresden (DE); Matthias Lehr, Dresden (DE); Alexander Platz, Ebersbach (DE)

Correspondence Address: Advanced Mirco Devices, Inc.;c/o Williams, Morgan & Amerson, 10333 Richmond, Suite 1100, Houston, TX, 77042, US

(21) Appl. No.: 12/648,517

(22) Filed: Dec. 29, 2009

(30) Foreign Application Priority Data
Dec. 31, 2008 (DE) 10 2008 063 401.8

(51) Int. Cl. H01L 23/498; H01L 21/60; H01L 21/768

(52) U.S. Cl. 257/737; 438/121; 257/690; 257/E23.06; 257/E21.589; 257/E21.506

(57) ABSTRACT

In sophisticated semiconductor devices, a chip-package interconnect structure may be established on the basis of a metal pillar without using a solder bump material in the package. In this case, the complexity of the manufacturing process for forming the wiring system of the package may be significantly reduced, while also providing the possibility of increasing packing density of the pillar structure.

### BACKGROUND OF THE INVENTION

1. Field of the Invention

Generally, the present disclosure relates to integrated circuits, and, more particularly, to techniques and devices for reducing chip-package interactions by providing chip-package connections based on metal pillars.

2. Description of the Related Art

Semiconductor devices are typically formed on substantially disc-shaped substrates made of any appropriate material. The majority of semiconductor devices including highly complex electronic circuits are currently, and in the foreseeable future will be, manufactured on the basis of silicon, thereby rendering silicon substrates and silicon-containing substrates, such as silicon-on-insulator (SOI) substrates, viable base materials for forming semiconductor devices, such as microprocessors, SRAMs, ASICs (application specific ICs), systems on chip (SoC) and the like. The individual integrated circuits are arranged in an array on the wafer, wherein most of the manufacturing steps, which may involve several hundred and more individual process steps in sophisticated integrated circuits, are performed simultaneously for all chip areas on the substrate, except for photolithography processes, metrology processes and packaging of the individual devices after dicing the substrate. Thus, economic constraints drive semiconductor manufacturers to steadily increase the substrate dimensions, thereby also increasing the area available for producing actual semiconductor devices and thus increasing production yield.

In addition to increasing the substrate area, it is also important to optimize the utilization of the substrate area for a given substrate size so as to actually use as much substrate area as possible for semiconductor devices and/or test structures that may be used for process control. In the attempt to maximize the useful surface area for a given substrate size, the feature sizes of circuit elements are steadily scaled down. Due to this ongoing demand for shrinking the feature sizes of highly sophisticated semiconductor devices, copper in combination with a low-k dielectric material has become a frequently used alternative in the formation of so-called interconnect structures comprising metal line layers and intermediate via layers that include metal lines as intra-layer connections and vias as inter-layer connections, which commonly connect individual circuit elements to provide the required functionality of the integrated circuit. Typically, a plurality of metal line layers and via layers stacked on top of each other is necessary to realize the connections between all internal circuit elements and I/O (input/output), power and ground pads of the circuit design under consideration.

For extremely scaled integrated circuits, the signal propagation delay is no longer limited by the circuit elements, such as field effect transistors and the like, but is limited, owing to the increased density of circuit elements that requires an even more increased number of electrical connections, by the close proximity of the metal lines, since the line-to-line capacitance is increased whereas conductivity of the lines is lowered due to a reduced cross-sectional area. For this reason, traditional dielectrics, such as silicon dioxide (k>4) and silicon nitride (k>7), are replaced by dielectric materials having a lower permittivity, which are, therefore, also referred to as low-k dielectrics having a relative permittivity of 3 or less.

Consequently, very efficient metallization systems may be provided in sophisticated semiconductor devices, which may allow the integration of an increasing number of functions into a single die area, thereby, however, also requiring sophisticated capabilities with respect to thermal and electrical connection to a corresponding package of the semiconductor device, while also requiring an increased number of individual input/output terminals, power and ground lines and the like. For these reasons, in the fabrication process for forming complex packaged integrated circuits, increasingly, a contact technology is used in connecting the package carrier to the chip, which is generally known as flip-chip packaging technique. Contrary to the well-established wire bonding techniques, in which appropriate contact pads are positioned at the periphery of the die area on the very last metal layer of the chip, which may then be connected to corresponding terminals of the package by a bond wire, in the flip-chip technology, a respective bump structure may be formed on the last metallization layer, for instance comprised of a solder material, which may be brought into contact with corresponding contact pads of the package. Thus, after re-flowing the solder material, a reliable electrical and mechanical connection is established between the last metallization layer and the contact pads of the package carrier. In this manner, a very large number of electrical connections may be provided across the entire chip area of the last metallization layer at reduced contact resistance and parasitic capacitance, thereby providing the input/output capabilities which may be required for complex integrated circuits, such as CPUs, storage memories and the like. In present contact technology, typically, solder material on the basis of lead is used, which, however, is considered inappropriate for future device generations in view of environmental issues caused by the lead material during the fabrication and after the lifetime of the semiconductor devices. Consequently, great efforts are currently being made in replacing the lead in the chip-package interconnect structures by other materials, such as solder materials using tin/silver or tin/silver/copper alloys and the like. The replacement of the lead material in well-established chip-package interconnect structures may, however, be associated with a plurality of challenges with respect to adapting corresponding manufacturing processes, while also maintaining reliability of the resulting interconnect structures. At the same time, there is a continuous demand for an increasing number of circuit functions incorporated into a single package, thereby typically requiring an increased number of electrical chip-package interconnections, which in turn may result in a reduced lateral size and pitch of the corresponding interconnect structures. Thus, the electrical connections may have to provide superior thermal and electrical conductivity at reduced dimensions, which has driven recent developments, in which the thermal and electrical performance of a “bump structure” may be increased by providing copper pillars instead of solder bumps or balls, thereby reducing the required floor space for the individual contact elements and also enhancing thermal and electrical conductivity due to the superior characteristics of copper compared to lead-free solder materials. These copper pillars may be formed with or without a corresponding cap made of a solder material and may then be connected to a complementary metallization level of the package, which has formed thereon a corresponding “bump structure” including a lead-free solder material, which may then provide the electrical and mechanical connection to the copper pillar upon re-flowing the lead-free solder material. The corresponding bump structure of the wiring system of the package may, however, require a complex manufacturing sequence, as will be described with reference to FIGS. 1a-1d.

FIG. 1a schematically illustrates a cross-sectional view of an integrated circuit 100 comprising a semiconductor chip 150 and a package substrate 170 that is to be connected to the semiconductor chip 150 by means of a pillar structure 160. The semiconductor chip 150 typically comprises a substrate 151, for instance a silicon substrate or an SOI substrate, depending on the overall configuration of the circuit layout and the performance requirements of the integrated circuit 100. The substrate 151 may comprise a semiconductor layer (not shown) in and above which may be provided a very large number of circuit elements, such as transistors, capacitors, resistors and the like, as are required for the desired functional behavior of the integrated circuit 100. For convenience, any such circuit elements are not shown in FIG. 1a. As previously discussed, the ongoing shrinkage of critical dimensions of circuit elements may result in critical dimensions of transistors on the order of magnitude of 50 nm and significantly less in presently available sophisticated semiconductor devices produced by volume production techniques. The semiconductor chip 150 comprises a metallization system 110, which comprises a plurality of metallization layers, i.e., of device levels in which metal lines and vias are embedded in an appropriate dielectric material. As discussed above, the pillar structure 160 is provided as a part of the metallization system 110, wherein the corresponding copper pillars 161 are provided in the very last metallization layer of the system 110. For example, the metallization system 110 comprises contact pads 111, a portion of which is exposed by a passivation layer 112, which is typically comprised of two or more material layers, such as a layer 112A, comprising, for instance, silicon dioxide, silicon oxynitride, silicon nitride and the like, followed by a further dielectric layer 112B, such as a polyimide layer and the like. As illustrated, the copper pillars 161 are formed on the passivation layer 112 so as to extend therefrom, while also directly connecting to the exposed portion of the contact pads 111. Hence, as previously explained, the pillar structure 160 may terminate the metallization system 110 so as to provide superior electrical and thermal behavior while the metal pillars 161 may be provided with reduced lateral dimensions and a corresponding pitch between adjacent copper pillars 161. Therefore, enhanced I/O capabilities may be provided on the basis of the pillar structure 160.

On the other hand, the package substrate 170 may be comprised of any appropriate material, such as an organic material, wherein also a corresponding wiring system 180 may be provided that may comprise, as a last metallization level, corresponding contact pads 181. The contact pads 181 may comprise an appropriate cap material, such as a nickel material, possibly in combination with other components, such as palladium, gold and the like, in order to provide superior conditions for forming thereon a bump structure 190, which may comprise a plurality of lead-free solder bumps 191, which are laterally embedded into an appropriate dielectric material, such as a resist material, polyimide and the like.

The integrated circuit 100, i.e., the semiconductor chip 150 and the package substrate 170, may be formed on the basis of the following process techniques. The semiconductor chip 150 is typically fabricated by sophisticated manufacturing strategies for providing circuit elements in and above the semiconductor layer (not shown), followed by sophisticated processes for forming the metallization system 110, which may typically include a plurality of individual metallization layers, as previously explained. After forming the final metallization layer of the system 110, including the contact pads 111, the passivation layer 112 may be deposited, on the basis of well-established deposition techniques, followed by a patterning sequence for forming openings connecting to the contact pads 111. Thereafter, a further process sequence may follow, in which an appropriate material, such as a resist material and the like, may be patterned to obtain appropriately sized openings, which are subsequently to be filled by copper material on the basis of electrochemical deposition techniques. Thereafter, the resist material is removed, thereby obtaining the pillar structure 160 as illustrated in FIG. 1a.

The package substrate 170 may also be formed on the basis of well-established manufacturing techniques, wherein the wiring system 180 may be formed so as to provide the required wiring layout for connecting the semiconductor chip 150 to peripheral components. Furthermore, after providing the contact pads 181 and forming thereon the cap material 182, the dielectric material 192 is deposited and appropriately patterned so as to obtain openings having dimensions that correspond to the lateral size of the bumps 191. Thereafter, the solder material is filled into the openings and a specific surface topography may be “embossed” into the bumps 191 in order to provide a reliable connection to the copper pillars 161 upon connecting the package 170 and the semiconductor chip 150. Thus, additional sophisticated manufacturing processes are required for providing the bump structure 190 on the wiring system 180 of each package substrate 170.

FIG. 1b schematically illustrates the integrated circuit 100 in a packaged state. That is, the package substrate 170 and the semiconductor chip 150 are attached to each other by the bump structure 190 and the pillar structure 160, which may be accomplished by appropriately aligning the substrate 170 to the chip 150, bringing these components into contact with each other and applying heat so as to re-flow the solder material of the bumps 191, thereby forming an inter-metallic connection region 193 between the remaining solder material of the bumps 191 and the copper pillars 161.

FIG. 1c schematically illustrates the integrated circuit 100 prior to connecting the package substrate 170 to the semiconductor chip 150 according to further conventional strategies. As illustrated, the copper pillars 161 may have formed on corresponding end faces thereof a lead-free solder material 162, which may also form an inter-metallic region 163 with the copper material of the pillars 161. In this case, the manufacturing sequence for forming the pillar structure 160 may comprise additional deposition steps for providing the solder material 162 and re-flowing the same in order to form the inter-metallic region 163. Thereafter, the further processing may be continued, as described above, wherein the presence of solder material in both the package substrate 170 and the semiconductor chip 150 may provide superior conditions when attaching the package 170 to the chip 150.

FIG. 1d schematically illustrates the integrated circuit 100 when the package 170 is connected to the semiconductor chip 150, i.e., the solder materials of the bumps 191 and 162 provide a stable electrical and mechanical connection.

Although a contact regime based on copper pillars may provide a possibility of using lead-free materials in combination with achieving superior electrical and thermal interconnect characteristics, the bump structure 190 of the package substrate 170 may require sophisticated additional manufacturing processes, thereby contributing to significant additional production costs. Moreover, a significant amount of solder material may be required as an interconnecting material, which may, therefore, result in increased lateral dimensions of a corresponding connection based on the solder material, which may thus reduce the possibility of increasing the density of electrical connections. Moreover, the presence of an increased amount of solder material may hinder the incorporation of a fill material that is typically positioned between the package 170 and the semiconductor chip 150 after connecting the same, which may thus result in the creation of corresponding cavities in the fill material, thereby contributing to a non-uniform thermal behavior of the entire interconnect structure. As previously discussed, frequently, sophisticated low-k dielectric materials are used in the metallization system 110 of the semiconductor chip 150, which may have a significantly reduced mechanical stability compared to conventional dielectric materials. Hence, any additional stress components, which may be exerted to the metallization system of the chip 150 during operation, for instance due to a mismatch of the coefficients of thermal expansion of the package 170 and the chip 150, increase the probability of creating severe defects in the metallization system 110, in particular if a non-uniform thermal conductivity may be created due to a non-uniform distribution of the fill material.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which a pillar structure may be used for the package-chip interconnect structure without providing a solder material at least in the wiring system of the package. Hence, in some illustrative aspects disclosed herein, a metallic contact between a package contact pad and the metal pillar may be established on the basis of a direct contact of copper-based materials, while, in other cases, appropriate cap materials may be used to form reliable interfaces connecting to the metal pillar and the package contact pad, respectively. In some illustrative embodiments, a lead-free solder material may also be provided on top of the metal pillars, however, with a significantly reduced amount, while the contact pads of the package may be provided without a solder material, thereby still maintaining the advantages of a significantly reduced overall complexity of the manufacturing sequence for forming the metallization system of the package. Moreover, due to the significant reduction of the amount of solder material, the lateral dimensions of a corresponding connection region formed between the package contact pad and the metal pillar may also be reduced, thereby enabling increased packing densities of the pillars, while also providing superior conditions for filling in a fill material with enhanced uniformity.

One illustrative packaged semiconductor device disclosed herein comprises a metallization system formed above a chip substrate, wherein the metallization system comprises a final metallization layer comprising a chip contact pad and a passivation layer formed on the final metallization layer so as to expose a portion of the chip contact pad. Furthermore, the semiconductor device comprises a metal pillar extending from the passivation layer, wherein the metal pillar is in contact with the chip contact pad. Additionally, a package wiring system is provided and comprises a final package metallization level comprising a package dielectric material and a package contact pad that is embedded in the package dielectric material. Finally, the semiconductor device comprises a solder-free connection region formed between the metal pillar and the package contact pad.

A further illustrative package semiconductor device disclosed herein comprises a metallization system formed above a chip substrate, which comprises a final metallization layer including a chip contact pad. Furthermore, the metallization system comprises a passivation layer formed on the final metallization layer, which exposes a portion of the chip contact pad. A metal pillar extends from the passivation layer and is in contact with the chip contact pad. Additionally, a package wiring system comprises a final package metallization level comprising a package dielectric material and a package contact pad that is embedded in the package dielectric material. Additionally, a lead-free connection region is formed between the metal pillar and the package contact pad, wherein the lead-free connection region has lateral dimensions that are substantially equal to lateral dimensions of the metal pillar and/or the package contact pad.

One illustrative method disclosed herein relates to connecting a package and a semiconductor chip. The method comprises forming a package wiring system having a final metallization level that comprises a package contact pad having an exposed surface. Moreover, the method comprises providing a solder-free first connection interface on the exposed surface. Finally, the method comprises connecting a second connection interface formed on a metal pillar of a metallization system of the semiconductor chip to the solder-free first connection interface.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of an integrated circuit during various manufacturing phases in connecting a package to a semiconductor chip based on sophisticated copper pillar structures and a solder bump structure formed on the package, according to conventional strategies;

FIGS. 2a-2b schematically illustrate cross-sectional views of a semiconductor device prior to and after connection of the package substrate, which may include a solder-free contact level, while the pillar structure of the semiconductor chip may comprise a lead-fee solder material, according to illustrative embodiments;

FIGS. 2c-2d schematically illustrate cross-sectional views of a semiconductor chip and a package prior to and after connection, according to still further illustrative embodiments, in which electrical and thermal contact may be established by appropriate materials formed on the package contact pad and the metal pillar;

FIGS. 2e-2f schematically illustrate cross-sectional views of the semiconductor chip and the package prior to and after connection, wherein the electrical contact may be established on the basis of a cap or interface material provided on the package contact pad, according to still further illustrative embodiments;

FIGS. 2g-2h schematically illustrate cross-sectional views of a semiconductor chip and the package prior to and after connection, wherein contact may be established substantially without any intermediate materials, according to still further illustrative embodiments; and

FIG. 2i schematically illustrates the package and the semiconductor chip during a manufacturing stage in which a passivation layer may be temporarily provided on the metal pillar and/or the contact pad prior to directly connecting these two components, according to yet other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides packaged semiconductor devices and techniques for forming the same in which enhanced thermal and electrical conductivity may be accomplished by means of a pillar structure, while nevertheless reducing the complexity of a corresponding manufacturing sequence and providing the potential of using highly complex metallization systems in the semiconductor chip. To this end, at least the package substrate may be provided substantially without any solder material formed thereon, thereby avoiding complex manufacturing techniques for depositing and patterning a corresponding dielectric material, which may be used as a template for filling in the lead-free solder material as is the case in conventional manufacturing strategies. According to the principles disclosed herein, the pillar structure, which may or may not comprise a lead-free solder material, may be directly connected to the package contact pad or a corresponding cap material formed thereon, thereby establishing a reliable mechanical and electrical connection, while also providing the possibility of reducing the lateral size of the pillar structure. That is, by avoiding significant amounts of solder material, the entire surface area of the package contact pad may be used for a direct contact with the metal pillar or a corresponding cap material formed thereon so that identical or superior electrical and thermal performance may be obtained for a reduced lateral size of the pillar and the package contact pad, since the connection may be established by using significantly reduced amounts of less-conductive solder material. Consequently, the design of the package contact pad may be adapted to the lateral size of the metal pillars, which in turn may result in superior overall performance of the connection, which in turn may enable the usage of sophisticated low-k dielectric materials in the metallization system of the semiconductor chip.

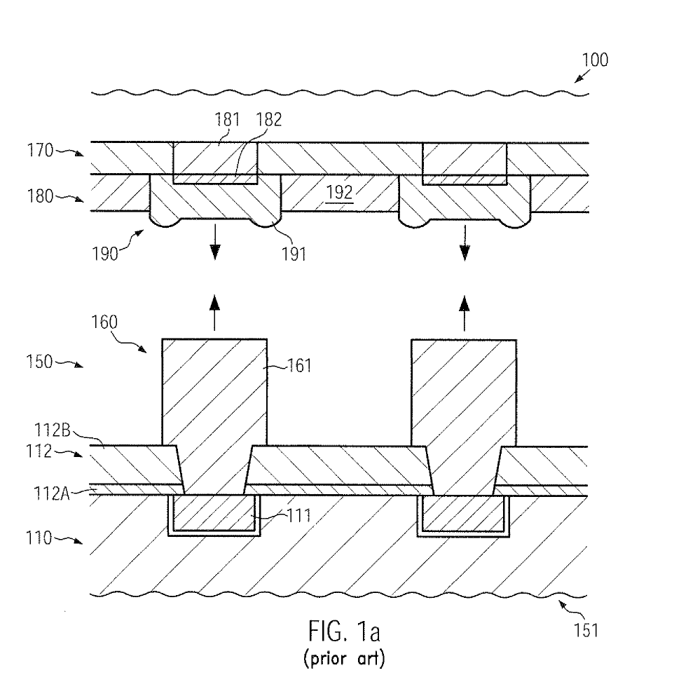

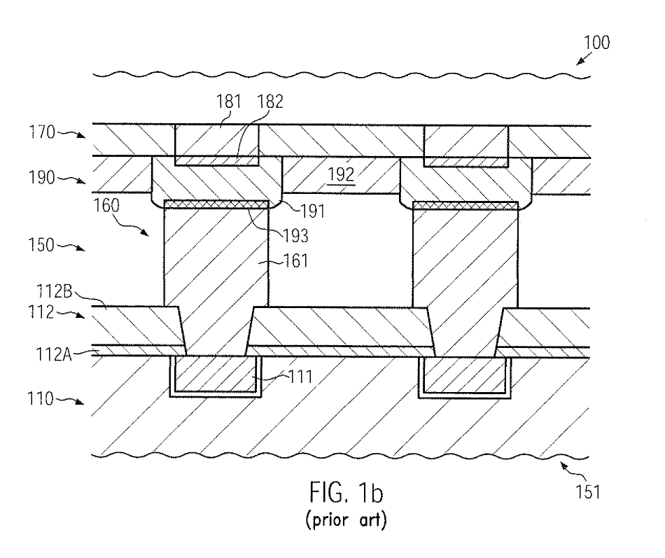

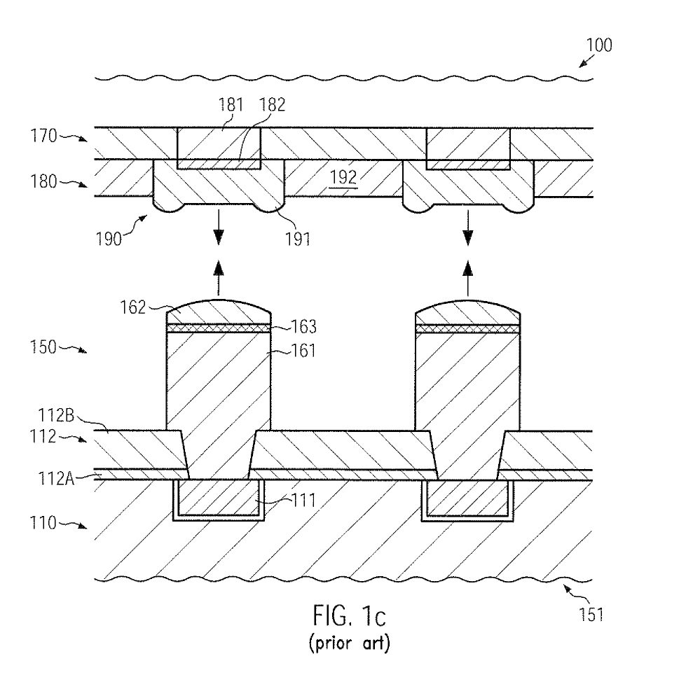

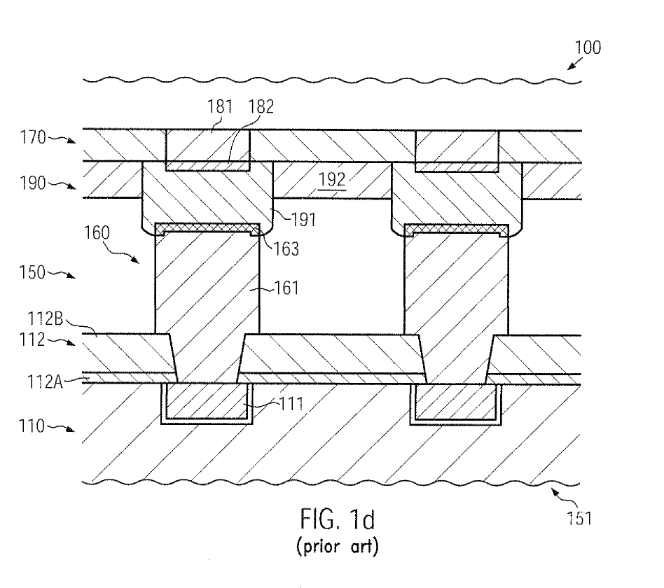

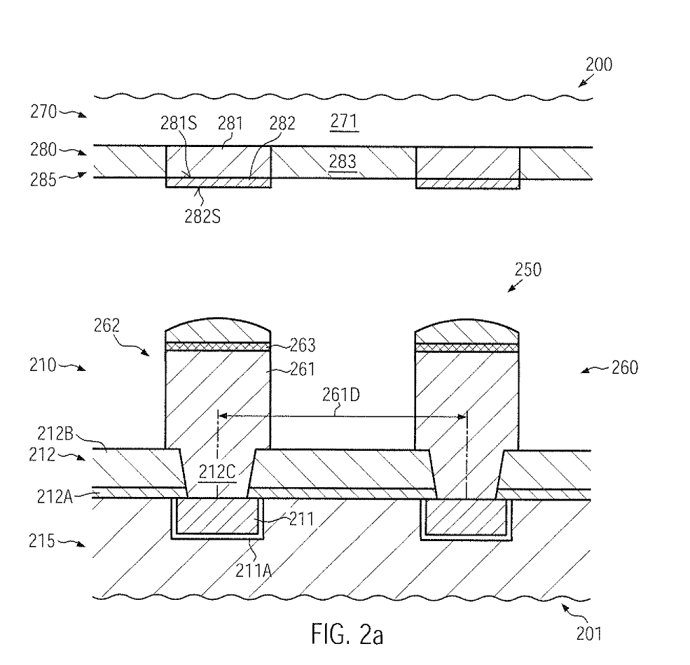

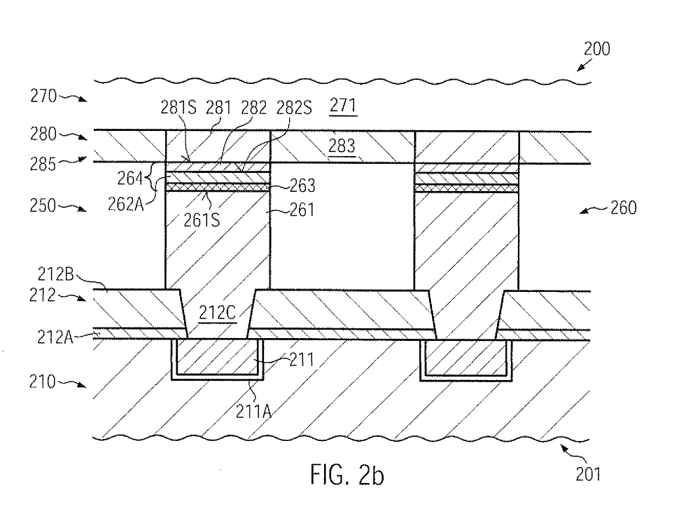

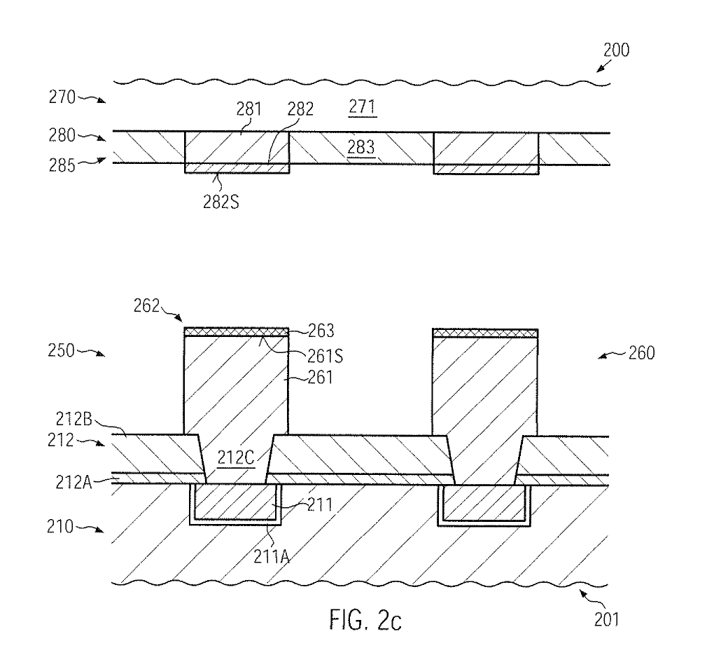

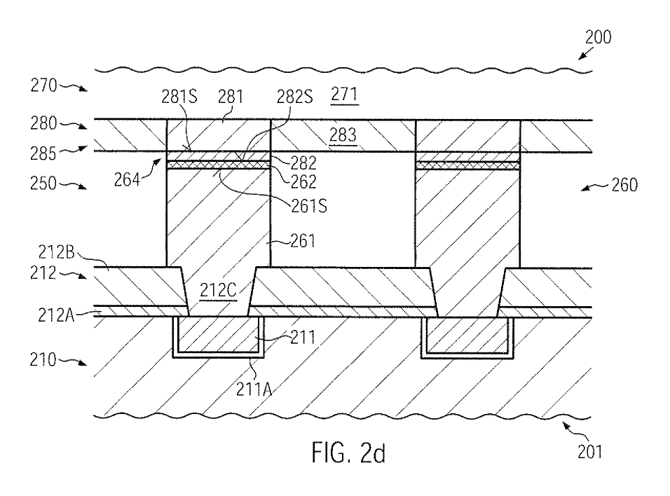

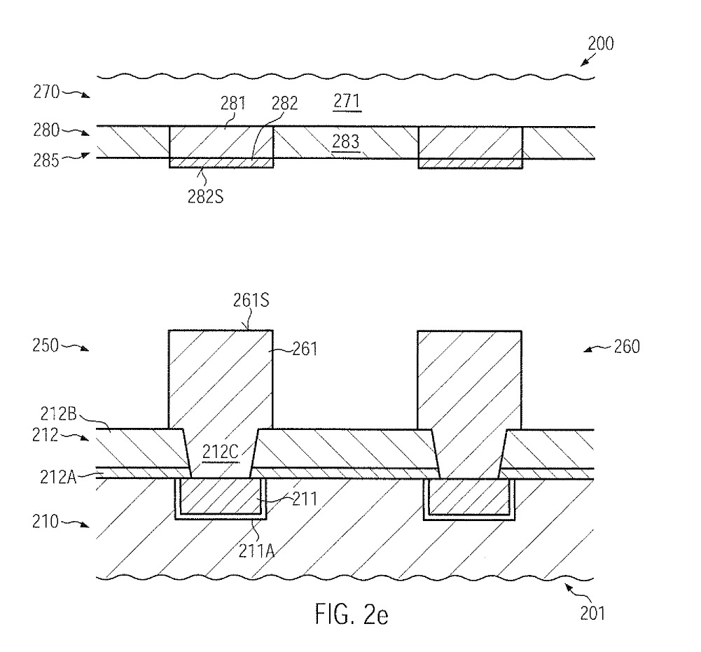

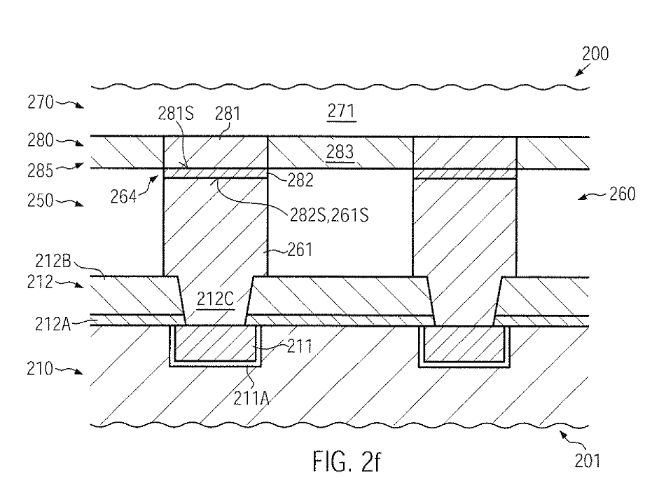

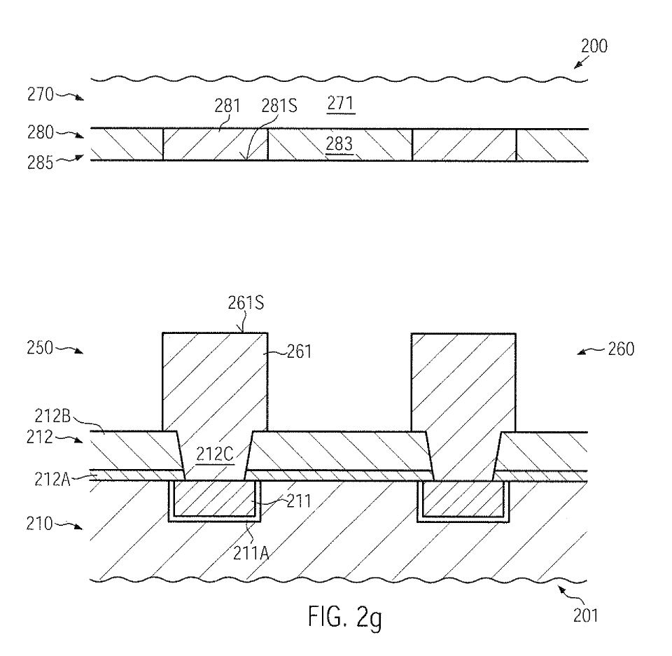

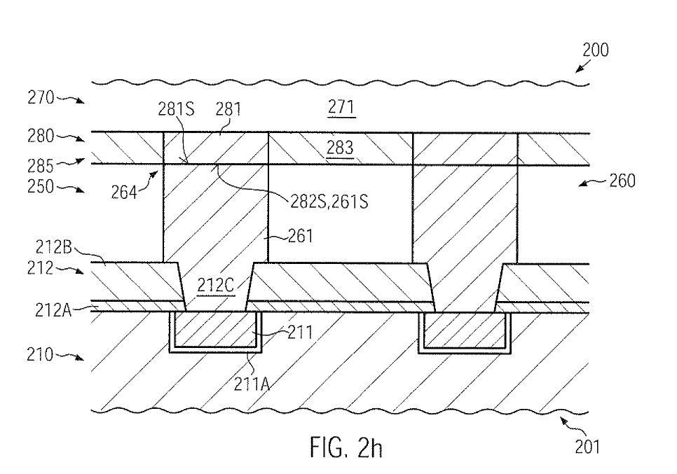

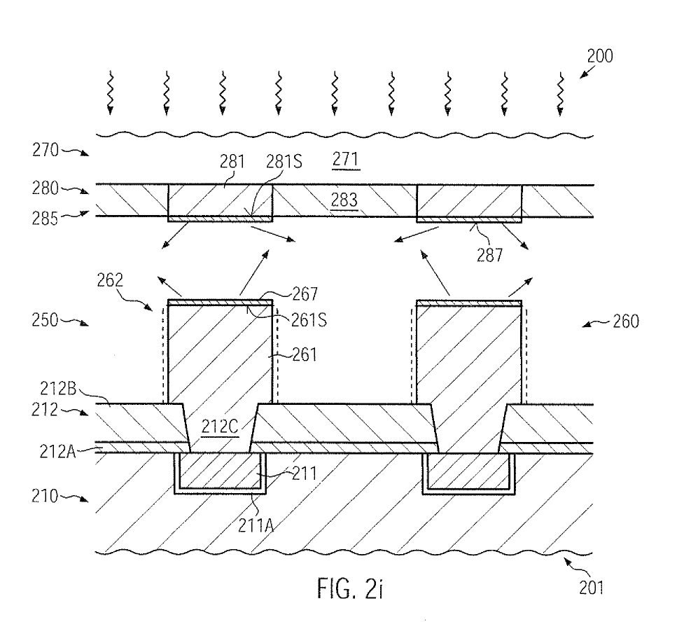

With reference to FIGS. 2a-2i, further illustrative embodiments will now be described in more detail, wherein reference may also be made to FIGS. 1a-1d if required.

FIG. 2a schematically illustrates a cross-sectional view of a semiconductor device or integrated circuit 200 comprising a package 270 and a semiconductor die or chip 250 in a non-connected state. The semiconductor chip 250 may comprise a substrate 201, above which may be formed circuit elements, such as transistors and the like, as is also previously described with reference to the integrated circuit 100 described with reference to FIGS. 1a-1d. Moreover, a metallization system 210 may be formed above the substrate 201 and may include a plurality of metallization layers (not shown), which may be formed on the basis of sophisticated dielectric materials, such as low-k dielectric materials having a dielectric constant of 3.0 less, or 2.7 or less, in which case these materials may also be referred to as ultra low-k (ULK) materials. Furthermore, the metallization system 210 may comprise a final metallization layer 215 comprising contact pads 211, which in some illustrative embodiments, may be comprised of a copper material, possibly in combination with a conductive barrier material 211A, for instance provided in the form of tantalum, tantalum-nitride, a combination thereof and the like. Additionally, the metallization system 210 may comprise a passivation layer 212 formed above the final metallization layer 215, wherein the layer 212 may have any appropriate configuration. For example, two or more sub-layers, such as layers 212A, 212B, may be provided in accordance with the required characteristics in view of passivating the final metallization layer 215. Furthermore, a metal pillar structure 260 comprising a plurality of metal pillars 261 electrically “terminates” the metallization system 210. That is, the pillars 261, which may be formed of copper in one illustrative embodiment, while, in other cases, any other highly conductive metal may be used, extend from the passivation layer 212 and are in contact with the contact pads 211. In the embodiment shown, the metal pillars 261 may be partially formed on the passivation layer 212, while, in other cases, the lateral size of the pillars 261 may substantially correspond to the lateral size of an opening 212C formed in the passivation layer 212, depending on the overall device requirements, for instance in view of contact density and the like. That is, in some cases, a distance 261D between adjacent pillars 261 may have to be reduced so as to provide a high density of contacts between the metallization system 210 and the package 270 so that a lateral size of the pillars 261 may be appropriately reduced, which in some cases may result in a lateral dimension that corresponds to the lateral size of the opening 212C. In this case, the size 212C may be selected so as to obtain the required mechanical stability of a corresponding pillar 261 while nevertheless providing an overall reduced lateral size. Consequently, in this case, any mechanical stress exerted on the pillar 261 may be more efficiently transferred into the passivation layer 212 and may thus be “distributed” across an increased area via more effective interaction of the copper pillar with sidewalls of the opening 212C.

Furthermore, in the embodiment shown, a cap structure 262 may be formed on the pillars 261, which may be comprised of a lead-free solder material, for instance in the form of a tin/silver alloy, or a tin/silver bismuth alloy, and the like. Furthermore, the cap structure 262 may comprise a region 263 forming an intermetallic connection with the material of the metal pillar 261. That is, the region 263 may comprise metal species of the pillar 261 and metal species of the lead-free solder material. It should be appreciated that the cap structure 262 including the lead-free solder material may, however, have incorporated therein a significantly reduced amount of solder material compared to conventional semiconductor devices, such as the integrated circuit 100, which may comprise a bump structure on the basis of a solder material, as previously discussed with reference to FIGS. 1a-1d.

The package 270 may comprise an appropriate substrate 271, for instance including organic materials and the like, in which an appropriate wiring system 280 may be incorporated. The wiring system 280 may thus comprise a final metallization level 285, which may comprise an appropriate dielectric material 283 with a plurality of package contact pads 281 incorporated in the dielectric material 283. In one illustrative embodiment, the package contact pads 281 are comprised of copper material. Thus, the contact pad 281 may provide a contact surface 281S on which, in the illustrative embodiment shown, a cap layer 282 may be formed to provide a connection interface 282S, which is to be put into contact with the pillar structure 260. For example, the cap layer 282 may comprise a nickel material, which, in some illustrative embodiments, may comprise a thin gold layer formed on the nickel material. In other illustrative embodiments, the cap layer 282 may comprise nickel, palladium and a final thin gold layer.

The semiconductor chip 250 may be formed on the basis of well-established manufacturing techniques, wherein, however, contrary to the conventional process strategies, previously described with reference to the integrated circuit 100, the lateral size of the pillars 261 may be adapted to the specific device requirements. That is, if required, a reduced distance 261D and a reduced lateral size of the pillars 261 may be used where desired. Furthermore, in the embodiment shown, the cap structure 262 may be formed on the basis of manufacturing techniques as previous described.

Similarly, the package 270 may be formed on the basis of well-established techniques for providing the wiring system 280, while, however, any further complex manufacturing processes required in conventional strategies for providing a bump structure may be omitted, thereby contributing to a significantly reduced overall process complexity. Furthermore, as previously explained, in some illustrative embodiments, the lateral size of the contact pads 281 may be adapted to the lateral size of the pillars 261, i.e., substantially the same lateral dimensions may be used for both components so as to obtain superior electrical and thermal conductivity, even if reduced lateral dimensions may be applied compared to conventional devices. In this respect, essentially identical lateral dimensions of two different components are to be understood as dimensions that are different by 10% or less of the lateral dimensions of one of the components. For example, the lateral dimension of the contact pad 281 is to be considered as substantially identical to the lateral dimension of the pillar 261, if a deviation of lateral dimension of the pad 281 along a predefined direction is 10% or less of the lateral dimension of the pillar 261 along the same specific lateral direction and if this holds for any lateral direction.

Thus, after providing the contact pads 281 with the desired dimensions, the cap layer 282 may be formed on the exposed surface 281S by electroless deposition techniques, possibly in combination with an immersion into an appropriate metal-containing solution, such as a gold-containing solution.

FIG. 2b schematically illustrates the semiconductor device 200 in a packaged state, i.e., in a state in which the package 270 is attached to the semiconductor chip 250. As illustrated, the pillar 261 is connected to the contact pad 281 via a connection region 264 which may comprise the cap layer 282, an inter-metallic region 263 and the remaining solder material 262A of the cap structure 262 (FIG. 2a). Thus, in one illustrative embodiment, the connection region 264 may connect with a first terminating interface 281S to the package contact pad 281 and with a second terminating interface 261S to the metal pillar 261 which may have been formed separately during the manufacturing sequences for forming package 270 and the semiconductor chip 250. Furthermore, the actual mechanical and electrical connection may be established via the interface 282S with the material 262A and cap layer 282. For example, in one illustrative embodiment, the interface 282S may be formed by a gold/solder material, when a final terminating gold layer may be formed in the cap layer 282, as previously explained. Furthermore, the connection region 264 may have a lateral dimension that, in some illustrative embodiments, is substantially identical to the lateral dimensions of the metal pillar 261 and the contact pad 281 in the above-defined sense. That is, upon bringing the package 270 and the chip 250 into mechanical contact and re-flowing the cap structure 263, a certain redistribution of the solder material 262A may occur, however, without unduly increasing the overall lateral dimensions, which may be advantageous when providing a high density of contact elements in the semiconductor device 200, at least in certain device areas.

FIG. 2c schematically illustrates the semiconductor device 200 prior to connecting the chip 250 and the package 270 according to still further illustrative embodiments. As illustrated, the metal pillars 261 comprise the cap structure 262 in the form of a gold layer and/or a palladium layer, thereby providing high conductivity and adhesion. It should be appreciated that other non-solder materials may also be used, if the desired electrical performance and mechanical stability may be accomplished. Thus, the terminating interface 261S may be formed on the basis of proper material of the pillar 261 and the metal of the cap structure 262, such as gold, palladium and the like. The cap structure 262 as illustrated in FIG. 2c may be formed on the basis of electrochemical deposition techniques, i.e., by electroless plating or electroplating, depending on the overall process strategy. For this purpose, an appropriate metal, such as gold, palladium and the like, may be deposited after filling in the material of the pillars 261 in a correspondingly designed deposition mask, as previously explained. Consequently, in some embodiments, the same deposition mask may also be used for providing a cap structure 262 by electroless techniques or electroplating techniques, wherein a corresponding current distribution material may also be used, as may previously be used for depositing the material of the pillars 261, when applying an electroplating process. Thereafter, the deposition mask and possibly a current distribution layer may be removed on the basis of well-established etch strategies. Consequently, the interface 261S may be provided in a highly stable and reliable manner.

FIG. 2d schematically illustrates the semiconductor device 200 in a packaged state. As illustrated, the connection region 264, including the terminating interfaces 281S and 261S, may comprise the interface 282S, which provides the actual electrical and mechanical connection between the package 270 and the chip 250. In one illustrative embodiment, the interface 282S may be established by gold/gold connection or gold/palladium connection, when the cap layer 282 comprises a gold layer as the final material layer and when gold or palladium are provided for the cap structure 262. The mechanical attachment of the components 270 and 250 may be accomplished by applying elevated temperatures and a moderately high pressure, wherein corresponding conditions may readily be determined on the basis of test runs based on process parameters as may typically be used in wire bonding techniques.

FIG. 2e schematically illustrates the semiconductor device 200 in a non-connected state according to further illustrative embodiments. As shown, the package 270 may be provided in a similar condition, as previously described, while the metal pillars 261 may have an exposed surface or terminating “interface” 261S. Consequently, the pillars 261 may be formed on the basis of a less complex manufacturing sequence, since additional deposition processes for depositing any cap materials may be omitted. In some illustrative embodiments, forming the pillars 261 may also include a process step for providing a temporary passivation layer (not shown) to enhance integrity of the surface 261S prior to connecting the chip 250 to the package 270. Corresponding surface treatments for forming a passivation layer will be described later on in more detail.

FIG. 2f schematically illustrates the semiconductor device 200 in a connected state, that is, the structure 270 is connected to the chip 250 so as to form the connection region 264, which is substantially comprised of the cap layer 282. That is, the actual contact may be established via the interface 282S or the surface 261S so that, in some illustrative embodiments, a gold/copper interface may be obtained, when gold is used as a final layer of the cap layer 282, while the pillar 261 is substantially comprised of copper. It should be appreciated, however, that additional metal species may be incorporated into the surface 261S, if considered appropriate for enhancing the overall performance with respect to thermal and electrical conductivity, electromigration behavior and/or mechanical adhesion. For instance, a metal species may be incorporated into the surface 261S by ion implantation, plasma surface treatment and the like.

FIG. 2g schematically illustrates the semiconductor device 200 wherein the package 270 may comprise contact pads 281 without any cap material, thereby providing the exposed surface 281S, such as a copper surface, when the contact pad 281 is comprised of copper material. Similarly, the pillars 261 may comprise the exposed surface 261S without providing any additional cap layer, while, as discussed above, a certain degree of metal species may be incorporated, for instance by implantation, plasma treatment and the like, if a certain degree of material modification may be considered appropriate. Consequently, reduced process complexity may be accomplished in both manufacturing the package 270 and the semiconductor chip 250, since corresponding deposition steps for forming cap structures and cap layers may be omitted. Moreover, consumption of raw materials, such as gold, palladium, nickel and the like, may be reduced during the entire manufacturing process when omitting the deposition of corresponding cap materials.

FIG. 2h schematically illustrates the semiconductor device 200 in a packaged state. That is, the package contact pad 281 and the pillar 261 are connected to each other via a “contact region” 264, which is substantially comprised of the interface defined by the surface areas 281S, 261S. For example, when the pad 281 and the pillar 261 are substantially comprised of copper, a copper/copper interface may be defined, wherein, as discussed above, additional metal species may also be present, if a corresponding surface treatment has been performed prior to connecting the package 270 and the chip 250. Also in this case, appropriate process conditions may be determined in advance, such as an appropriate temperature and a mechanic pressure in order to obtain a reliable electrical and mechanical attachment of the pad 281 and the pillar 261. Consequently, a highly conductive connection between the chip 250 and the package 270 may be accomplished due to the direct connection of highly conductive materials, while at the same time overall process complexity and material consumption may be reduced.

FIG. 2i schematically illustrates the semiconductor device 200 at an appropriate manufacturing stage prior to connecting the package 270 to the chip 250, wherein the contact pad 281 and/or the copper pillar 261 may comprise a sacrificial cap material. For example, in some embodiments, the exposure of the surface 281S and/or of the surface 261S may be considered inappropriate, for instance in view of creating contaminations such as corrosion and the like, which may frequently be the case in exposed copper surface areas. Thus, in some illustrative embodiments, a sacrificial cap layer 287 may be formed on the exposed surface 281S and/or a sacrificial cap layer 267 may be formed on the exposed surface 261S, which, in some illustrative embodiments, may be accomplished by immediately exposing the surfaces 281S, 261S to a reactive ambient after forming the contact pad 281 and/or the pillar 261. For instance, a plurality of corrosion-inhibiting materials, such as triazole and any derivative thereof, such as benzene triazole (BTA), are well established candidates for treating copper surfaces in order to reduce corrosion, wherein a passivation layer may also form that may allow further treatment of the devices without significant copper contamination. For example, a corresponding exposure to a corrosion-inhibiting material may be formed after removing a corresponding deposition mask and possibly removing any current distribution layers that may have been used for forming the pillars 261. In this case, the corresponding sacrificial cap layer 267 may also form on sidewalls of the pillar 261, as indicated by the dashed line. In other cases, an appropriate sacrificial cap layer may be formed immediately after depositing the material of the pillars 261 in the presence of the corresponding deposition mask, thereby restricting formation of the cap layer 267 to the surface 261S. It should be appreciated that other materials may be used for forming the layers 287 and/or 267, wherein, in some illustrative embodiments, these materials may have a high degree of volatility so as to be removable upon application of elevated temperatures, which may typically be used during the process of connecting the structure 270 and the chip 250. Consequently, in some illustrative embodiments, immediately prior to actually contacting the pad 281 and the pillar 261, the process conditions may be adjusted such, for instance in the form of an elevated temperature, so as to vaporize the layers 287 and/or 267, thereby providing a moderately clean surface while also reducing the probability of creating contaminations during the bonding process.

It should be appreciated that a corresponding sacrificial cap layer may also be provided at any process stages, in which only one of the components, i.e., the pad 281 or the pillar 261, as a highly reactive surface area. For example, as previously described with reference to FIG. 2e, a connection may be established by using the cap layer 287 or the contact pad 281, while the pillar 261 may be connected with its exposed surface 261S to the cap layer 287. In this case, the sacrificial cap layer 267 may also be used in order to enhance reliability and performance of the resulting connection. Similarly, if the contact pad 281 is exposed, while the pillar 261 may have formed thereon an appropriate cap structure (not shown), the layer 287 may be provided on the package contact pad 281 in order to reduce surface contamination.

As a result, the present disclosure provides packaged semiconductor devices and corresponding manufacturing techniques in which solder-free wiring systems of the package may be used to form an interconnect structure on the basis of metal pillars provided on the metallization system of the semiconductor chip. Consequently, complex deposition and patterning processes for providing a bump structure on the package may be avoided.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A packaged semiconductor device, comprising:
a metallization system formed above a chip substrate, said metallization system comprising a final metallization layer comprising a chip contact pad, said metallization system further comprising a passivation layer formed above said final metallization layer and exposing a portion of said chip contact pad;
a metal pillar having a contact surface that extends above a surface of said passivation layer, said metal pillar being in contact with said chip contact pad;
a package wiring system comprising a final package metallization level comprising a package dielectric material and a package contact pad embedded in said package dielectric material; and
a solder-free connection region formed between said metal pillar and said package contact pad.

2. The semiconductor device of claim 1, wherein said solder-free connection region comprises at least one of gold, nickel and palladium.

3. The semiconductor device of claim 1, wherein said solder-free connection region is substantially comprised of copper.

4. The semiconductor device of claim 1, wherein said package contact pad and said metal pillar have substantially identical lateral dimensions.

5. The semiconductor device of claim 1, wherein said solder-free connection region has lateral dimensions that are substantially identical to a lateral dimension of at least one of said package contact pad and said metal pillar.

6. The semiconductor device of claim 1, wherein said connection region comprises a first terminating interface connecting to said metal pillar and a second terminating interface connecting to said package contact pad, wherein said first and second terminating interfaces have different material compositions.

7. The semiconductor device of claim 6, wherein said first terminating interface is comprised of at least one of gold and palladium.

8. The semiconductor device of claim 6, wherein said second terminating interface comprises nickel.

9. The semiconductor device of claim 5, wherein said connection region comprises a first terminating interface connecting to said metal pillar and a second terminating interface connecting to said package contact pad, wherein said first and second terminating interfaces have substantially the same material composition.

10. The semiconductor device of claim 9, wherein said first and second terminating interfaces comprise at least one of nickel, gold and palladium.

11. The semiconductor device of claim 1, wherein said package contact pad and said metal pillar are comprised of copper.

12. The semiconductor device of claim 11, wherein said chip contact pad is comprised of copper.

13. A packaged semiconductor device, comprising:
a metallization system formed above a chip substrate, said metallization system comprising a final metallization layer comprising a chip contact pad, said metallization system further comprising a passivation layer formed above said final metallization layer and exposing a portion of said chip contact pad;
a metal pillar having a contact surface that extends above a surface of said passivation layer, said metal pillar being in contact with said chip contact pad;
a package wiring system comprising a final package metallization level comprising a package dielectric material and a package contact pad embedded in said package dielectric material; and
a lead-free connection region formed between said metal pillar and said package contact pad, said lead-free connection region having lateral dimensions that are substantially equal to lateral dimensions of at least one of said metal pillar and said package contact pad.

14. The packaged semiconductor device of claim 13, wherein said connection region comprises a solder material that forms an intermetallic connection with said metal pillar.

15. The packaged semiconductor device of claim 14, wherein said connection region further comprises an interface connecting to said package contact pad, wherein said interface is substantially free of solder material.

16. The packaged semiconductor device of claim 15, wherein said interface comprises at least one of nickel, gold and palladium.

17. The semiconductor device of claim 16, wherein said package contact pad and said metal pillar are comprised of copper.

18. A method of connecting a package and a semiconductor chip, the method comprising:
forming a package wiring system having a final metallization level comprising a package contact pad, said package contact pad having an exposed surface;
providing a solder-free first connection interface on said exposed surface; and
connecting a second connection interface formed on a metal pillar of a metallization system of said semiconductor chip to said solder-free first connection interface.

19. The method of claim 18, wherein providing said first connection interface comprises forming one or more metal species on said exposed surface.

20. The method of claim 18, wherein forming said one or more metal species comprises depositing at least one of nickel, palladium and gold.

21. The method of claim 20, wherein forming said one or more metal species comprises forming gold as a final material layer above said exposed surface.

22. The method of claim 18, wherein providing said first connection interface comprises using said exposed surface as said first connection interface.

23. The method of claim 18, wherein providing said first connection interface comprises forming a passivation layer on said exposed surface, removing said passivation layer and using said exposed surface as said first connection interface.

24. The method of claim 18, further comprising forming said second connection interface on said metal pillar by forming a lead-free solder material above said metal pillar prior to connecting said second connection interface to said first connection interface.

25. The method of claim 18, further comprising forming said second connection interface on said metal pillar by forming at least one of gold and palladium on said metal pillar.

26. The method of claim 18, further comprising providing said second connection interface by using an exposed end face of said metal pillar as said second connection interface.

27. The method of claim 18, further comprising providing said second connection interface by forming a passivation layer on an exposed end face of said metal pillar, removing said passivation layer and using said exposed end face as said second connection interface.
